(19) United States
(12) Patent Application Publication
(10) Pub. No.: US 2026/0024591 A1
(43) Pub. Date: Jan. 22, 2026

(54) FLOATING GATE-BASED PARTIAL BLOCK HANDLING IN A MEMORY SUB-SYSTEM

(71) Applicant: MICRON TECHNOLOGY, INC., Boise, ID (US)

(72) Inventors: Hanping Chen, San Jose, CA (US); Ching-Huang Lu, Fremont, CA (US); Fulvio Rori, Boise, ID (US); Zhongguang Xu, San Jose, CA (US); Murong Lang, San Jose, CA (US); Yu-Chung Lien, San Jose, CA (US); Zhenming Zhou, San Jose, CA (US)

(21) Appl. No.: 19/273,964

(22) Filed: Jul. 18, 2025

Related U.S. Application Data
(60) Provisional application No. 63/673,948, filed on Jul. 22, 2024.

(51) Int. Cl. G11C 16/26; G11C 16/04

(52) U.S. Cl. CPC G11C 16/26; G11C 16/0483

(57) ABSTRACT

An example system includes: a memory array and a processing device, operatively coupled to the memory array. The processing device is configured to: receive a request to read a subset of memory cells of the memory array; initiate ramping up of a first passthrough voltage to be applied to at least one unselected programmed wordline associated with the subset of memory cells; initiate ramping up of a second passthrough voltage to be applied to at least one unprogrammed wordline associated with the subset of memory cells; cause, during the ramping up of the second passthrough voltage applied to the at least one unselected programmed wordline, the unprogrammed wordline to be electrically disconnected from a voltage source; and cause a read voltage level to be applied to a selected wordline associated with the subset of memory cells.

### REFERENCE TO RELATED APPLICATION

This application claims the priority benefit of U.S. Provisional Patent Application No. 63/673,948, filed Jul. 22, 2024, the entirety of which is incorporated herein by reference.

### TECHNICAL FIELD

Embodiments of the disclosure relate generally to memory sub-systems, and more specifically, relate to floating gate-based partial block handling in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system, in accordance with one or more embodiments of the present disclosure.

FIG. 1B is a block diagram of a memory device in communication with a memory sub-system controller of a memory sub-system, in accordance with one or more embodiments of the present disclosure.

FIG. 2A-2D are schematics of portions of an array of memory cells as could be used in a memory of the type described with reference to FIG. 1B, in accordance with one or more embodiments of the present disclosure.

FIG. 3 is a block schematic of a portion of an array of memory cells as could be used in a memory of the type described with reference to FIG. 1B, in accordance with one or more embodiments of the present disclosure.

FIG. 4 schematically illustrates example voltage levels to be applied to the programmed and unprogrammed wordlines during a read operation, in accordance with aspects of the present disclosure.

FIGS. 5A-5B schematically illustrate the floating gate control on the unprogrammed wordlines, in accordance with aspects of the present disclosure.

FIG. 6 schematically illustrates the early ramp up of the passthrough voltage supplied to the source side select gate (SGS) and dummy wordlines (DMY) in accordance with aspects of the present disclosure.

FIG. 7 schematically illustrates the delayed ramp down of the passthrough voltage 701 supplied to the source side select gate (SGS) and dummy wordlines (DMY) in accordance with aspects of the present disclosure.

FIG. 8 schematically illustrates example half-good block (HGB) structures, in accordance with aspects of the present disclosure.

FIG. 9 schematically illustrates a flow diagram of an example method of performing a memory read operation, in accordance with aspects of the present disclosure.

FIG. 10 is a block diagram of an example computer system in which embodiments of the present disclosure may operate.

### DETAILED DESCRIPTION

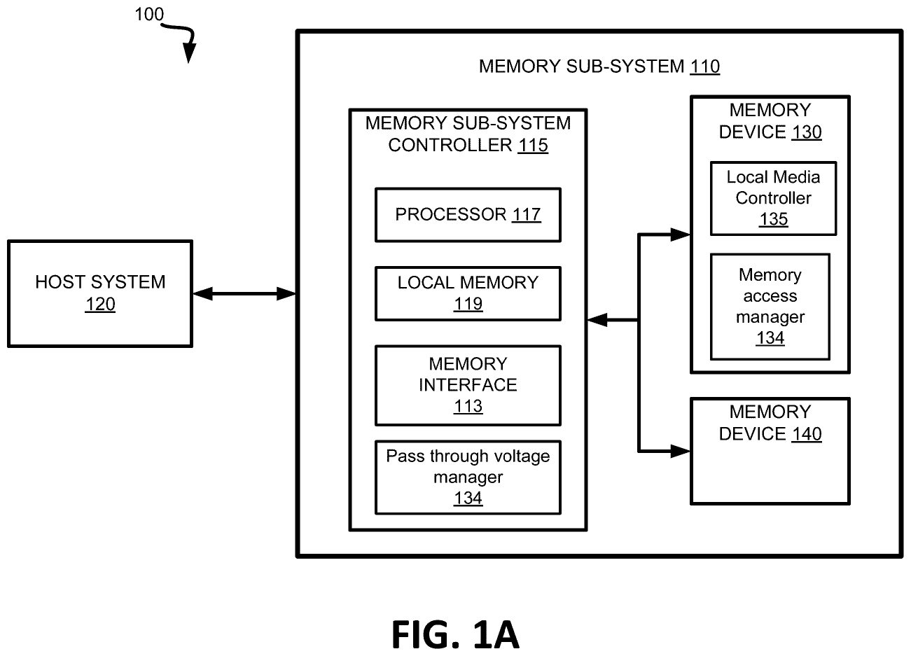

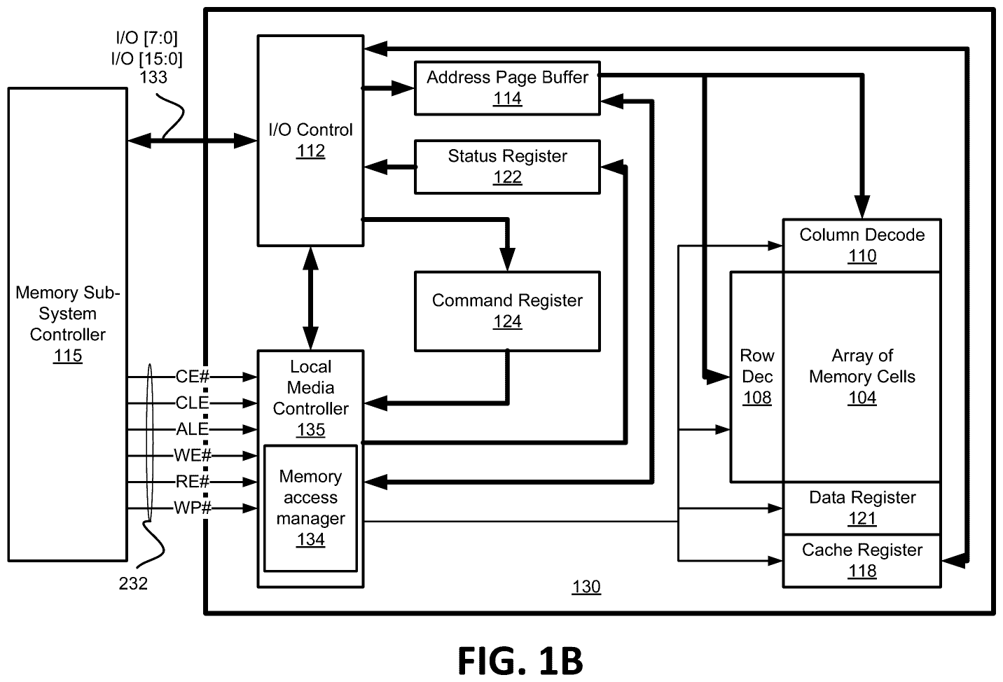

Aspects of the present disclosure are directed to floating gate-based partial block handling in a memory sub-system. A memory sub-system can be a storage device, a memory module, or a combination of a storage device and memory module. Examples of storage devices and memory modules are described below in conjunction with FIGS. 1A-1B. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIGS. 1A-1B. A non-volatile memory device is a package of one or more dies. Each die includes one or more planes. For some types of non-volatile memory devices (e.g., NAND devices), each plane includes a set of physical blocks. Each block consists of a set of pages. Each page includes a set of memory cells. A memory cell is an electronic circuit that stores information. Depending on the memory cell type, a memory cell can store one or more bits of binary information, and has various logic states that correlate to the number of bits being stored. The logic states can be represented by binary values, such as “0” and “1”, or combinations of such values.

A memory device (e.g., a memory die) can include memory cells arranged in a two-dimensional or a three-dimensional grid. The memory cells are formed onto a silicon wafer in an array of columns and rows. The memory cells are joined by wordlines, which are conducting lines electrically connected to the control gates of the memory cells, and bitlines, which are conducting lines electrically connected to the drain electrodes of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane.

To achieve high density, a string of memory cells in a non-volatile memory device can be constructed to include a number of memory cells at least partially surround a pillar of channel material. The memory cells can be coupled to access lines, which are commonly referred to as “wordlines,” often fabricated in common with the memory cells, so as to form an array of strings in a block of memory. The compact nature of certain no-volatile memory devices, such as 3D flash NAND memory, means that a given wordline can be shared by multiple memory cells within a block of memory.

A memory cell can store one or more bits of information in the form of electric charge characterized by the threshold voltage (Vₜ), which is a lowest voltage at which the cell can be activated (i.e., switched on). During a read operation and a program verify operation, a read reference voltage (V_{ref}) can be applied to an associated wordline, and a sense amplifier connected to an associated bitline can be used to sense whether the read cell has been switched on. Thus, only one cell per bitline can be read at a time. Since the cells of a bitline are connected in series, all transistors for cells of the bitline that are not being read (“unread cells”) need to be kept on during the read operation in order for the read output of the read cell to passthrough to the sense amplifier. To achieve this, a passthrough voltage (Vₚₐₛₛ) can be applied to the wordlines of the unread cells to keep the unread cells on.

The threshold voltage levels may be affected by various physical phenomena (e.g., the slow charge loss) and thus may change with time, temperature, etc. Thus, in order to reduce the error rate, a memory device may track the read voltage levels for various sections of the memory device.

As blocks are sequentially programmed wordline-by-wordline, one or more partially programmed block may exist at any given point in time. Compared to a fully-programmed block, the memory cell characteristics of a partially-programmed block may be different due to, e.g., the cell-to-cell effect, the back-pattern effect, and the lateral charge movement effect, which may lead to the read voltage levels being different in a fully-programmed block and in a partially-programmed block. However, the read voltage levels are usually tracked for the fully-programmed blocks. Applying such a read level to a partially-programmed block can lead to a higher read bit error rate (RBER) which, in turn, may trigger additional media management operations (e.g., folding).

In some implementations, a memory sub-system may mitigate the undesired effects associated with the partially-programmed state of blocks by padding the partially-programmed blocks (i.e., storing random or pattern data to the unprogrammed part of the block). However, padding may become prohibitively expensive with the increasing block size.

Accordingly, in some implementations, a memory sub-system may adjust the read levels for the wordlines of partially-programmed blocks by the values stored in a look-up table. However, the size of such a look-up table would grow with the increasing memory device capacity.

Accordingly, in some implementations, during a read operation, a lower passthrough voltage (V_{pass_low}) may be applied to the unprogrammed wordlines as compared to the programmed wordlines. This lower passthrough voltage would change the bias voltage level of the unprogrammed wordlines, thus allowing the use of the same read voltage level for all wordlines, which in turn would eliminate the need for padding of the partially programmed blocks or the look-up table to keep the per-wordline voltage level.

However, while the V_{pass_low} may be sourced from a dedicated voltage source in each plane, adding the new voltage regulator may be an undesirable design option. Alternatively, the V_{pass_low} may be sourced from a voltage regulator which is shared with other biases, but the exact specified bias voltage may be difficult to find among the existing bias voltage.

Aspects of the present disclosure address the above and other deficiencies by implementing the floating gate control on the unprogrammed wordlines, by electrically disconnecting (floating) the unprogrammed wordlines during the ramp-up of the passthrough voltage applied to the programmed wordlines (Vₚₐₛₛ). However, the minimum wordline bias resulting from floating the wordline during the ramp-up phase would be limited by a non-zero value.

Accordingly, in some implementations, the passthrough voltage level supplied to the source-side select gate (SGS) and dummy wordlines (DMY) may be ramped up earlier than the passthrough voltage applied to the unprogrammed data wordlines, which would result in earlier discharge of the channel potential. Alternatively, the passthrough voltage level supplied to the source-side select gate (SGS) and dummy wordlines (DMY) may be ramped down later than the passthrough voltage applied to the unprogrammed data wordlines, thus preventing the channel from coupling the data wordlines down at the end of the read operation.

Thus, the passthrough voltage (V_{pass_low}) applied to the unprogrammed wordlines would be controlled by the combination of the floating gate delay and the SGS ramp timing, as described in more detail herein below. Implementations described herein do not require additional voltage regulators, therefore avoiding additional costs and footprint. Furthermore, implementations described herein do not rely upon a look-up table for tracking the read voltage levels for partially-programmed blocks. Furthermore, implementations described herein do not require padding of partially-programmed blocks. Furthermore, implementations described herein may result in lower read bit error rate (RBER) resulting from the read operations.

The methods described herein apply to partially-programmed blocks, partially-good blocks (e.g., half good blocks and third good blocks), partially-programmed blocks within partially-good blocks, and/or block-by-deck implementations.

FIG. 1A illustrates an example computing system 100 that includes a memory sub-system 110 implemented in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Pillar, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory, including two-dimensional NAND (2D NAND) and three-dimensional NAND (3D NAND).

Each of the memory devices 130 can include one or more arrays of memory cells. One type of memory cell, for example, single level memory cells (SLC) can store one bit per memory cell. Other types of memory cells, such as multi-level memory cells (MLCs), triple level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCS, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory page buffers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

The local media controllers 135 can implement a memory access manager 134 that can implement the memory access operations (e.g., read operations) in accordance with aspects of the present disclosure. In particular, the memory access manager 134 may control the floating gate delay and the SGS ramp timing during execution of read operations of one or more memory pages of the memory device 130.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 110 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address page buffer 114 is in communication with I/O control circuitry 160 and row decode circuitry 108 and column decode circuitry 110 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 110 to control the row decode circuitry 108 and column decode circuitry 110 in response to the addresses. In one embodiment, local media controller 135 includes the memory access manager 134, which can implement the memory access operations (e.g., read operations) in accordance with aspects of the present disclosure.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 121 for transfer to the array of memory cells 104; then new data may be latched in the cache register 118 from the I/O control circuitry 160. During a read operation, data may be passed from the cache register 118 to the I/O control circuitry 160 for output to the memory sub-system controller 115; then new data may be passed from the data register 121 to the cache register 118. The cache register 118 and/or the data register 121 may form (e.g., may form a portion of) a page buffer of the memory device 130. A page buffer or register may further include sensing devices (not shown in FIG. 1B) to sense a data state of a memory cell of the array of memory cells 204, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command register 124. The addresses may be received over input/output (I/O) pins [7:0] of I/O bus 136 at I/O control circuitry 160 and may then be written into address page buffer 114. The data may be received over input/output (I/O) pins [7:0] for an 8-bit device or input/output (I/O) pins [15:0] for a 16-bit device at I/O control circuitry 160 and then may be written into cache register 118. The data may be subsequently written into data register 121 for programming the array of memory cells 104.

In an embodiment, cache register 118 may be omitted, and the data may be written directly into data register 121. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

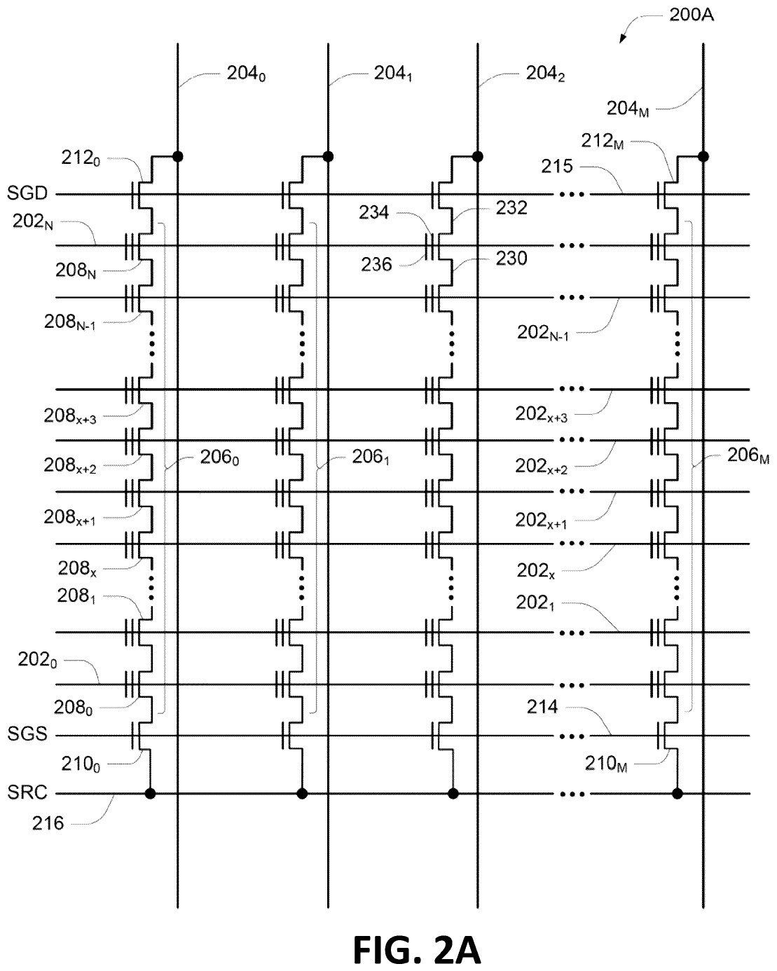

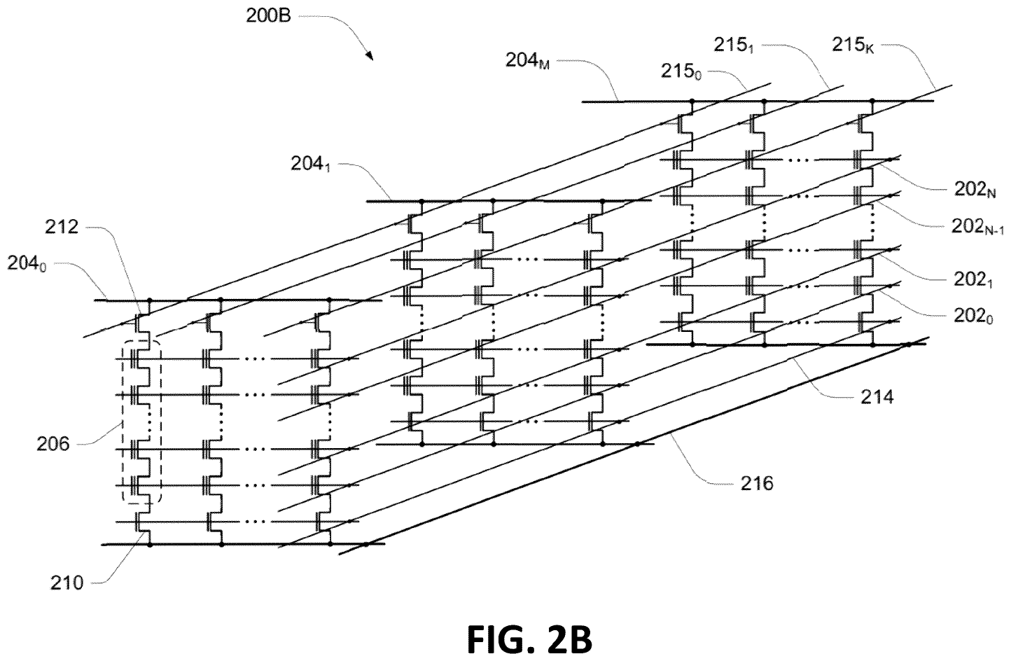

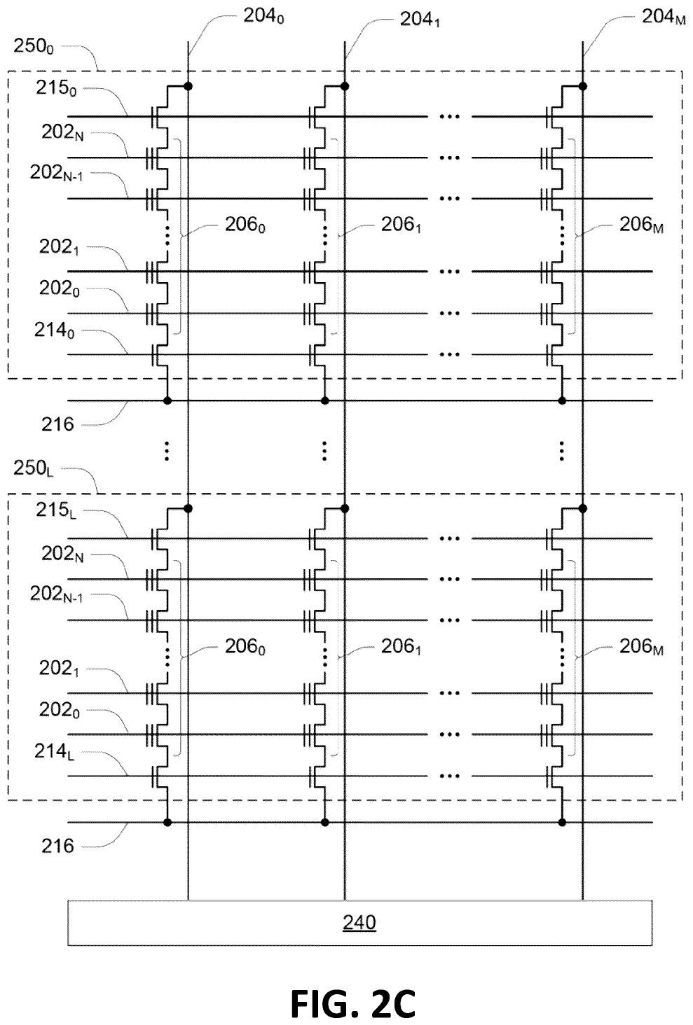

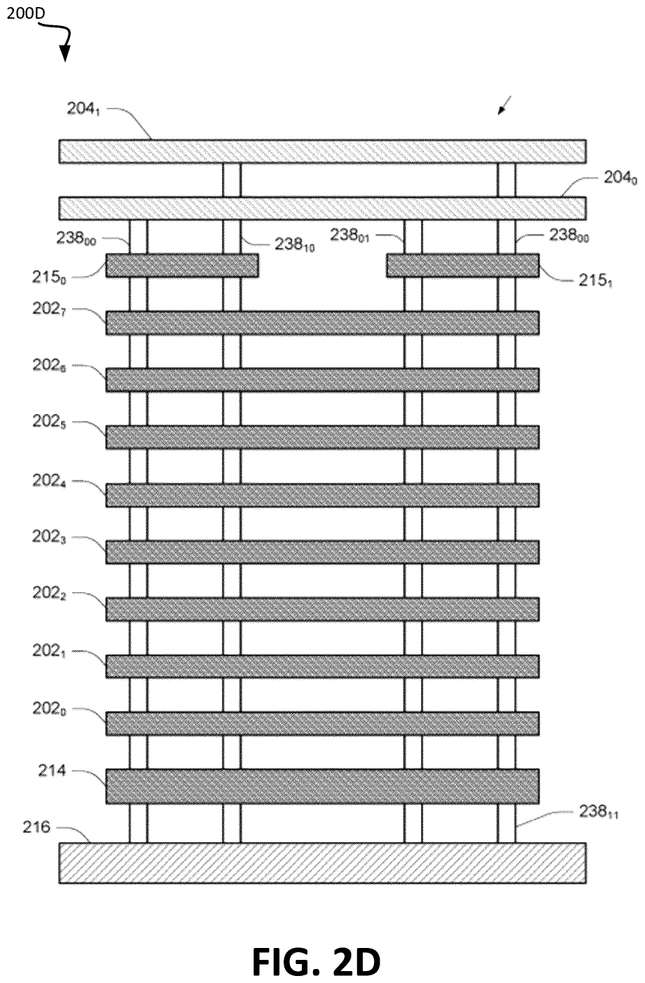

FIGS. 2A-2C are diagrams of portions of an example array of memory cells included in a memory device, in accordance with some embodiments of the present disclosure. For example, FIG. 2A is a schematic of a portion of an array of memory cells 200A as could be used in a memory device (e.g., as a portion of array of memory cells 104). Memory array 200A includes access lines, such as wordlines 202₀ to 202_{N}, and a data line, such as bitline 204. The wordlines 202 may be connected to global access lines (e.g., global wordlines), not shown in FIG. 2A, in a many-to-one relationship. For some embodiments, memory array 200A may be formed over a semiconductor that, for example, may be conductively doped to have a conductivity type, such as a p-type conductivity, e.g., to form a p-well, or an n-type conductivity, e.g., to form an n-well.

Memory array 200A can be arranged in rows each corresponding to a respective wordline 202 and columns each corresponding to a respective bitline 204. Rows of memory cells 208 can be divided into one or more groups of physical pages of memory cells 208, and physical pages of memory cells 208 can include every other memory cell 208 commonly connected to a given wordline 202. For example, memory cells 208 commonly connected to wordline 202_{N} and selectively connected to even bitlines 204 (e.g., bitlines 204₀, 204₂, 204₄, etc.) may be one physical page of memory cells 208 (e.g., even memory cells) while memory cells 208 commonly connected to wordline 202_{N} and selectively connected to odd bitlines 204 (e.g., bitlines 204₁, 204₃, 204₅, etc.) may be another physical page of memory cells 208 (e.g., odd memory cells). Although bitlines 204₃-204₅ are not explicitly depicted in FIG. 2A, it is apparent from the figure that the bitlines 204 of the array of memory cells 200A may be numbered consecutively from bitline 204₀ to bitline 204_{M}. Other groupings of memory cells 208 commonly connected to a given wordline 202 may also define a physical page of memory cells 208. For certain memory devices, all memory cells commonly connected to a given wordline might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells may include those memory cells that are configured to be erased together, such as all memory cells connected to wordlines 202₀-202_{N} (e.g., all strings 206 sharing common wordlines 202). Unless expressly distinguished, a reference to a page of memory cells herein refers to the memory cells of a logical page of memory cells.

Each column can include a string of series-connected memory cells (e.g., non-volatile memory cells), such as one of strings 206₀ to 206_{M}. Each string 206 can be connected (e.g., selectively connected) to a source line 216 (SRC) and can include memory cells 208₀ to 208_{N}. The memory cells 208 of each string 206 can be connected in series between a select gate 210, such as one of the select gates 210₀ to 210_{M}, and a select gate 212, such as one of the select gates 212₀ to 212_{M}. In some embodiments, the select gates 210₀ to 210_{M} are source-side select gates (SGS) and the select gates 212₀ to 212_{M} are drain-side select gates. Select gates 210₀ to 210_{M} can be connected to a select line 214 (e.g., source-side select line) and select gates 212₀ to 212_{M} can be connected to a select line 215 (e.g., drain-side select line). The select gates 210 and 212 might represent a plurality of select gates connected in series, with each select gate in series configured to receive a same or independent control signal. A source of each select gate 210 can be connected to SRC 216, and a drain of each select gate 210 can be connected to a memory cell 208₀ of the corresponding string 206. Therefore, each select gate 210 can be configured to selectively connect a corresponding string 206 to SRC 216. A control gate of each select gate 210 can be connected to select line 214. The drain of each select gate 212 can be connected to the bitline 204 for the corresponding string 206. The source of each select gate 212 can be connected to a memory cell 208_{N} of the corresponding string 206. Therefore, each select gate 212 might be configured to selectively connect a corresponding string 206 to the bitline 204. A control gate of each select gate 212 can be connected to select line 215.

In some embodiments, and as will be described in further detail below with reference to FIG. 2B, the memory array in FIG. 2A is a three-dimensional memory array, in which the strings 206 extend substantially perpendicular to a plane containing SRC 216 and to a plane containing a plurality of bitlines 204 that can be substantially parallel to the plane containing SRC 216.

FIG. 2B is another schematic of a portion of an array of memory cells 200B (e.g., a portion of the array of memory cells 104) arranged in a three-dimensional memory array structure. The three-dimensional memory array 200B may incorporate vertical structures which may include semiconductor pillars where a portion of a pillar may act as a channel region of the memory cells of strings 206. The strings 206 may be each selectively connected to a bit line 204₀-204_{M} by a select gate 212 and to the SRC 216 by a select gate 210. Multiple strings 206 can be selectively connected to the same bitline 204. Subsets of strings 206 can be connected to their respective bitlines 204 by biasing the select lines 215₀-215_{L} to selectively activate particular select gates 212 each between a string 206 and a bitline 204. The select gates 210 can be activated by biasing the select line 214. Each wordline 202 may be connected to multiple rows of memory cells of the memory array 200B. Rows of memory cells that are commonly connected to each other by a particular wordline 202 may collectively be referred to as tiers.

FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation, sometimes referred to as erase blocks. Each block of memory cells 250 can represent those NAND strings 206 commonly associated with a single select line 215, e.g., select line 215₀. The source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bitlines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bitlines 204.

FIG. 2D is a diagram of a portion of an array of memory cells 200D (e.g., a portion of the array of memory cells 104). Channel regions (e.g., semiconductor pillars) 238₀₀ and 238₀₁ represent the channel regions of different strings of series-connected memory cells (e.g., strings 206 of FIGS. 2A-2C) selectively connected to the bitline 204₀. Similarly, channel regions 238₁₀ and 238₁₁ represent the channel regions of different strings of series-connected memory cells (e.g., NAND strings 206 of FIGS. 2A-2C) selectively connected to the bitline 204₁. A memory cell (not depicted in FIG. 2D) may be formed at each intersection of a wordline 202 and a channel region 238, and the memory cells corresponding to a single channel region 238 may collectively form a string of series-connected memory cells (e.g., a string 206 of FIGS. 2A-2C). Additional features might be common in such structures, such as dummy wordlines, segmented channel regions with interposed conductive regions, etc.

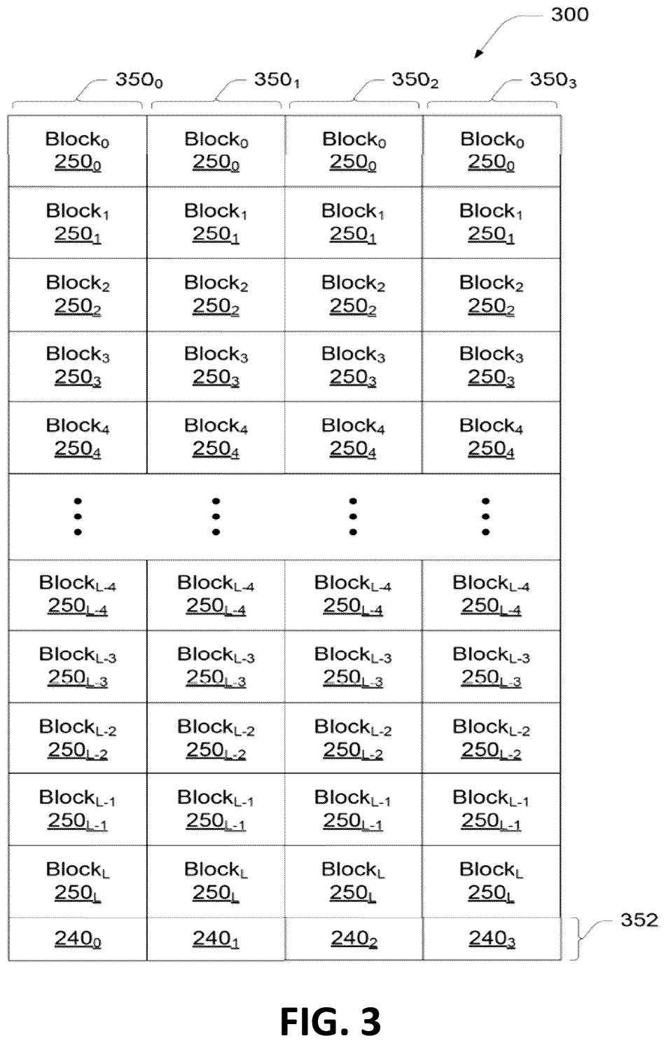

FIG. 3 is a block schematic of an example portion of an array of memory cells 300 as could be used in a memory of the type described with reference to FIG. 1B. The array of memory cells 300 is depicted as having four memory planes 350 (e.g., memory planes 350₀-350₃), each in communication with a respective buffer portion 240, which can collectively form a page buffer 352. While four memory planes 350 are depicted, other numbers of memory planes 350 can be commonly in communication with a page buffer 352. Each memory plane 350 is depicted to include L+1 blocks of memory cells 250 (e.g., blocks of memory cells 250₀-250_{L}).

As noted herein above, a memory device operating in accordance with aspects of the present disclosure may control the passthrough voltage (V_{pass_low}) applied to the unprogrammed wordlines by the combination of the floating gate delay and the SGS ramp timing. In particular, the memory device may implement the floating gate control on the unprogrammed wordlines, by electrically disconnecting (floating) the unprogrammed wordlines during the ramp-up of the passthrough voltage applied to the programmed wordlines (Vₚₐₛₛ). Furthermore, in some implementations, the passthrough voltage level supplied to the source side select gate (SGS) and dummy wordlines (DMY) may be ramped up earlier than the passthrough voltage applied to the unprogrammed data wordlines, which would result in earlier discharge of the channel potential. Alternatively, the passthrough voltage level supplied to the source side select gate (SGS) and dummy wordlines (DMY) may be ramped down later than the passthrough voltage applied to the unprogrammed data wordlines, thus preventing the channel from coupling the data wordlines down at the end of the read operation.

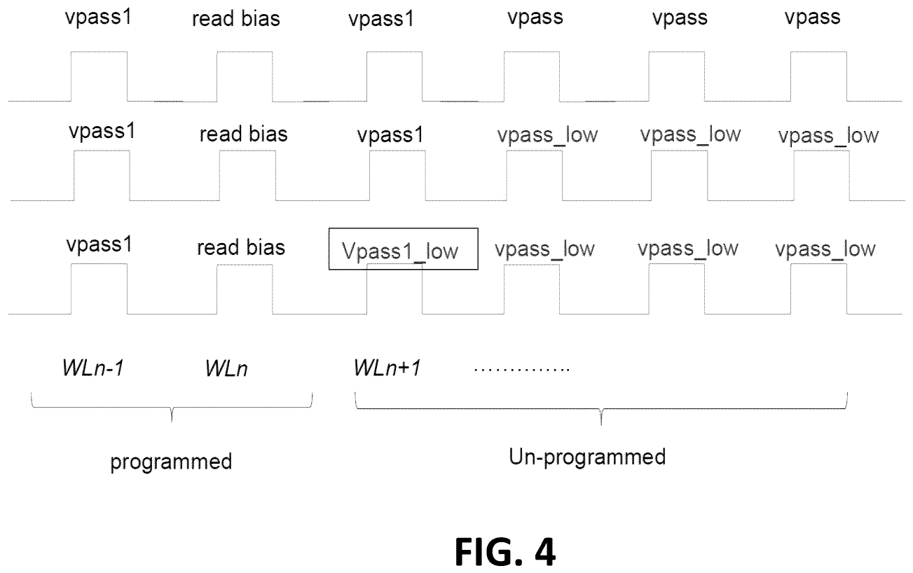

FIG. 4 schematically illustrates example voltage levels to be applied to the programmed and unprogrammed wordlines during a read operation, in accordance with aspects of the present disclosure. In FIG. 4, plot 401 illustrates the default mode of operation applying the same passthrough voltage to all unprogrammed wordlines; plot 402 illustrates application of a lower passthrough voltage to the inner unprogrammed wordlines; and plot 403 illustrates application of a lower passthrough voltage to the boundary unprogrammed wordlines.

As schematically illustrated by FIG. 4, the default mode of operation plot 401 applies read bias voltage to the target wordline (WLₙ), while applying the default passthrough voltage (Vₚₐₛₛ) to the unprogrammed inner wordlines and applying lower passthrough voltage (Vₚₐₛₛ₁) to the boundary wordlines WLₙ₋₁ and WLₙ₊₁.

Conversely, the plot 402 applies a lower (as compared to the default passthrough voltage (Vₚₐₛₛ)) passthrough voltage (V_{pass_low}) to the unprogrammed inner source side wordlines WLₙ₊₂ . . . WLₙ₊ₖ.

Furthermore, the plot 403 applies a lower (as compared to the default passthrough voltage (Vₚₐₛₛ)) passthrough voltage (V_{pass_low}) to the unprogrammed inner wordlines, while applying a lower (as compared to the passthrough voltage Vₚₐₛₛ₁) passthrough voltage (V_{pass_low1}) to the unprogrammed boundary wordline WLₙ₊₁.

The lower passthrough voltages (V_{pass_low} and V_{pass_low1}) applied to the unprogrammed wordlines may be controlled by the combination of the floating gate delay and the SGS ramp timing, as described in more detail herein below.

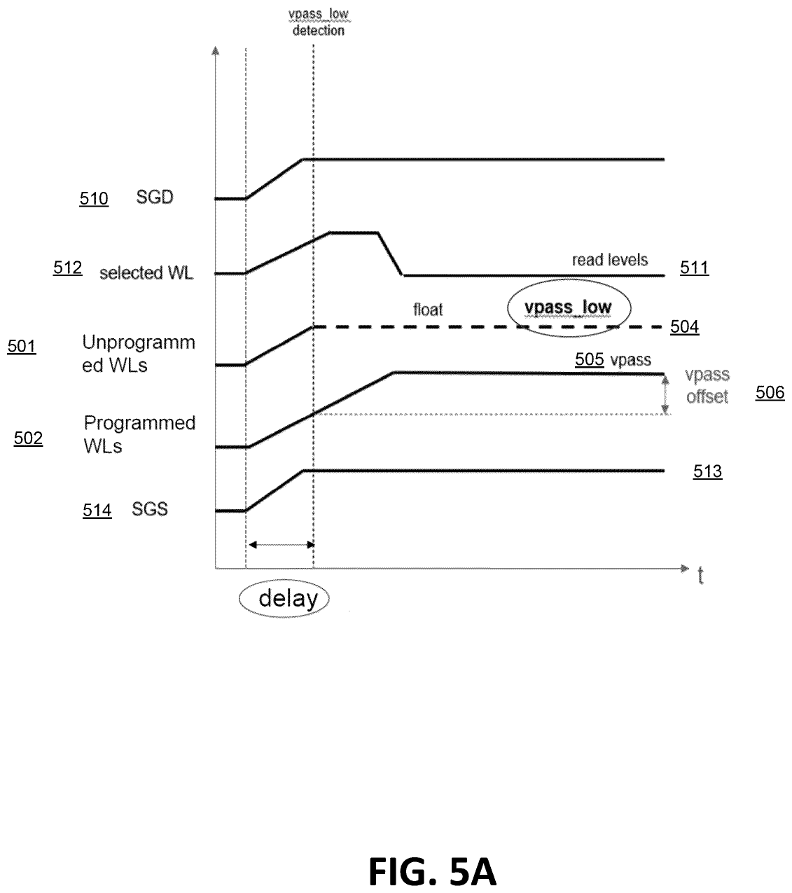

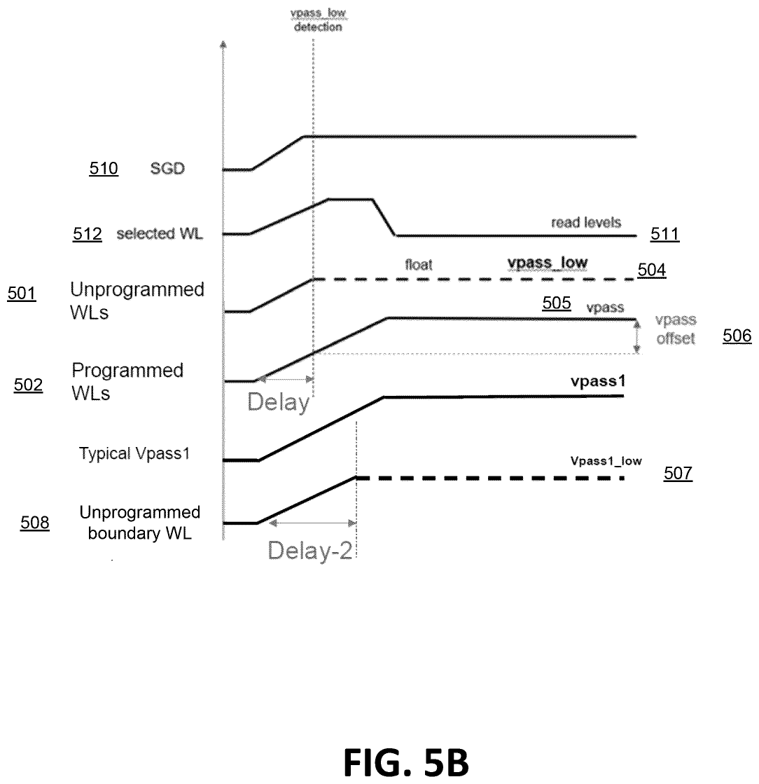

FIGS. 5A-5B schematically illustrate the floating gate control on the unprogrammed wordlines, in accordance with aspects of the present disclosure. As schematically illustrated by FIG. 5A, the unprogrammed wordlines 501 may be floated (i.e., disconnected from the voltage source) during the ramp-up of the passthrough voltage (Vₚₐₛₛ) applied to the programmed wordlines 502. In some implementations, the unprogrammed wordlines 501 may be floated when ramping up voltage on the unprogrammed wordlines 501 reaches the desired value (V_{pass_low}) 504. The moment in time when the unprogrammed wordlines 501 are floated is characterized by the delay 503 with respect to the start of the ramping up phase of the passthrough voltages applied to the programmed and unprogrammed wordlines.

Floating the unprogrammed wordlines results in the lower passthrough voltage (V_{pass_low}) 504 being effectively applied to the unprogrammed wordlines. The difference between the passthrough voltage (Vₚₐₛₛ) 505 applied to the programmed wordlines 502 and the lower passthrough voltage (V_{pass_low}) 504 applied to the unprogrammed wordlines 501 is schematically illustrated as the passthrough voltage offset 506.

In some implementations, a specified voltage 510 can be applied to the drain side select gate (SGDs); a read level voltage 511 can be applied to the selected wordline 512; a specified passthrough voltage 513 can be applied to the source side select gate (SGSs) 514, as described in more detail herein below.

In some implementations, as schematically illustrated by FIG. 5B, the lower (as compared to the default passthrough voltage (Vₚₐₛₛ)) passthrough voltage (V_{pass_low}) may be applied to the unprogrammed inner wordlines, while further lowering (as compared to the passthrough voltage Vₚₐₛₛ₁) the passthrough voltage (V_{pass1_low}) 507 that is applied to the unprogrammed boundary wordlines (WLₙ₊₁) 508. In some implementations, the boundary wordlines 508 may be floated when ramping up voltage on the boundary wordlines 508 reaches the desired value (V_{pass1_low}) 507. The moment in time when the boundary wordlines 508 are floated is characterized by the delay 509 with respect to the start of the ramping up phase of the passthrough voltages applied to the programmed and unprogrammed wordlines.

Alternatively, the floating gate delay described with reference to FIG. 5A may be combined with a look-up table for storing the read level shift values for the boundary wordlines.

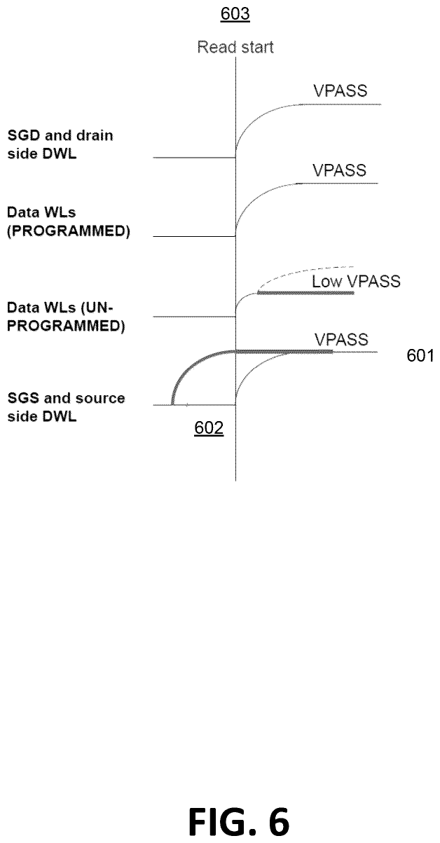

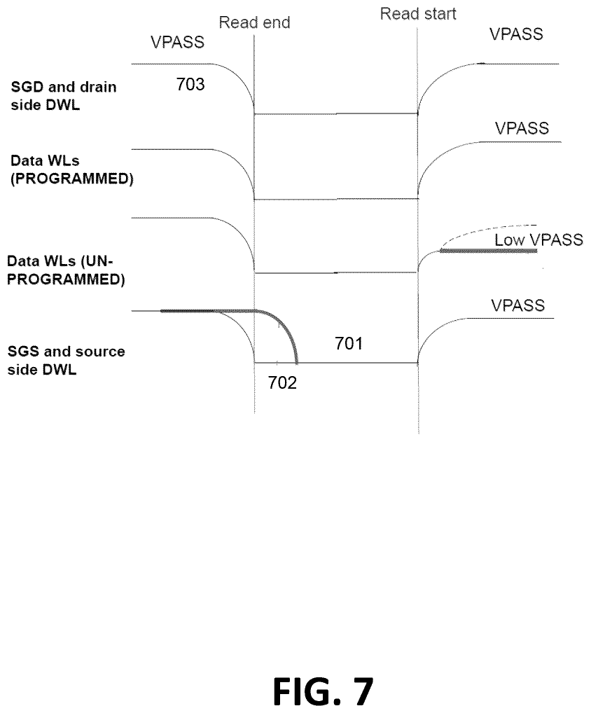

However, as noted herein above, the minimum wordline bias resulting from floating the wordline during the ramp-up phase would be limited by a non-zero value. Accordingly, in some implementations, the passthrough voltage level supplied to the source side select gate (SGS) and dummy wordlines (DMY) may be ramped up earlier than the passthrough voltage applied to the unprogrammed data wordlines, which would result in earlier discharge of the channel potential, as schematically illustrated by FIG. 6. Alternatively, the passthrough voltage level supplied to the source side select gate (SGS) and dummy wordlines (DMY) may be ramped down later than the passthrough voltage applied to the unprogrammed data wordlines, thus preventing the channel from coupling the data wordlines down at the end of the read operation, as schematically illustrated by FIG. 7.

FIG. 6 schematically illustrates the early ramp up of the passthrough voltage supplied to the source side select gate (SGS) and dummy wordlines (DMY) in accordance with aspects of the present disclosure. As schematically illustrated by FIG. 6, the ramp up of the passthrough voltage 601 supplied to the source side select gate (SGS) and dummy wordlines (DMY) may be initiated by at least a predefined period of time 602 earlier with respect to the ramp up 603 of other passthrough voltages, which would result in earlier discharge of the channel potential, thus preventing the undesirable coupling up of the floated unprogrammed wordlines.

FIG. 7 schematically illustrates the delayed ramp down of the passthrough voltage 701 supplied to the source side select gate (SGS) and dummy wordlines (DMY) in accordance with aspects of the present disclosure. As schematically illustrated by FIG. 7, the ramp down of the passthrough voltage 701 supplied to the source side select gate (SGS) and dummy wordlines (DMY) may be initiated by at least a predefined period of time 702 later with respect to the ramp down 703 of other passthrough voltages, thus preventing the channel from coupling the data wordlines down at the end of the read operation.

In some implementations, the low passthrough voltage values applied to the unprogrammed wordlines may be temperature-dependent. In an illustrative example, the dependence may be expressed by a monotonically decreasing function (e.g., a decreasing linear function).

As noted herein above, the methods described herein apply to partially-programmed blocks, partially-good blocks (e.g., half good blocks and third good blocks), partially-programmed blocks within partially-good blocks, and/or block-by-deck implementations.

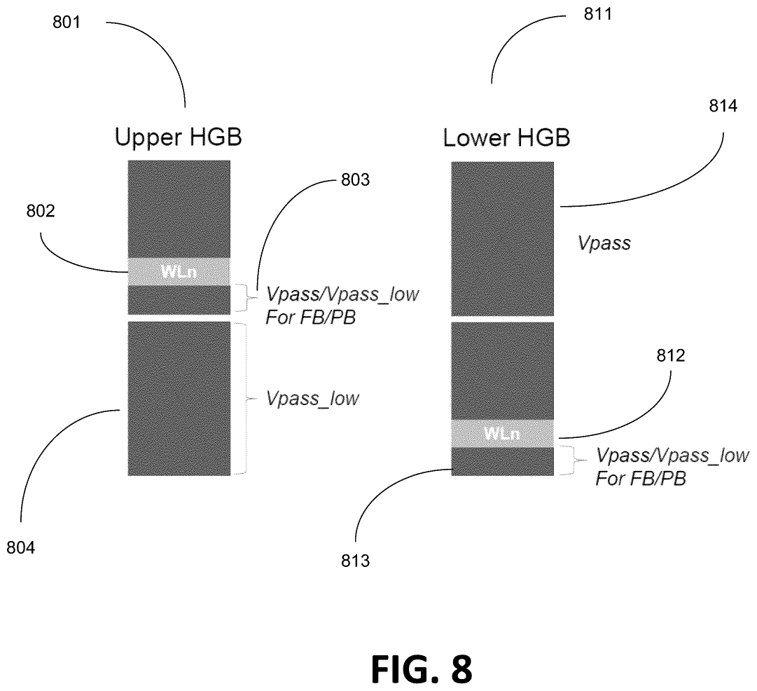

FIG. 8 schematically illustrates the example half-good block (HGB) 801, in which the good half-block resides in the upper deck of a memory device. Accordingly, the last programmed wordline (WLₙ) 802 would also reside in the upper deck. Thus, the lower passthrough voltage (V_{pass_low}) may be applied to both the unprogrammed wordlines 803 of the upper deck and to all wordlines 804 of the lower deck.

Conversely, for the example half-good block (HGB) 811, in which the good half-block resides in the lower deck of a memory device, the last programmed wordline (WLₙ) 812 would also reside in the upper deck. Accordingly, the lower passthrough voltage (V_{pass_low}) may only be applied to the unprogrammed wordlines 813 of the lower deck, while the default passthrough voltage (Vₚₐₛₛ) may be applied to the wordlines 814 of the upper deck.

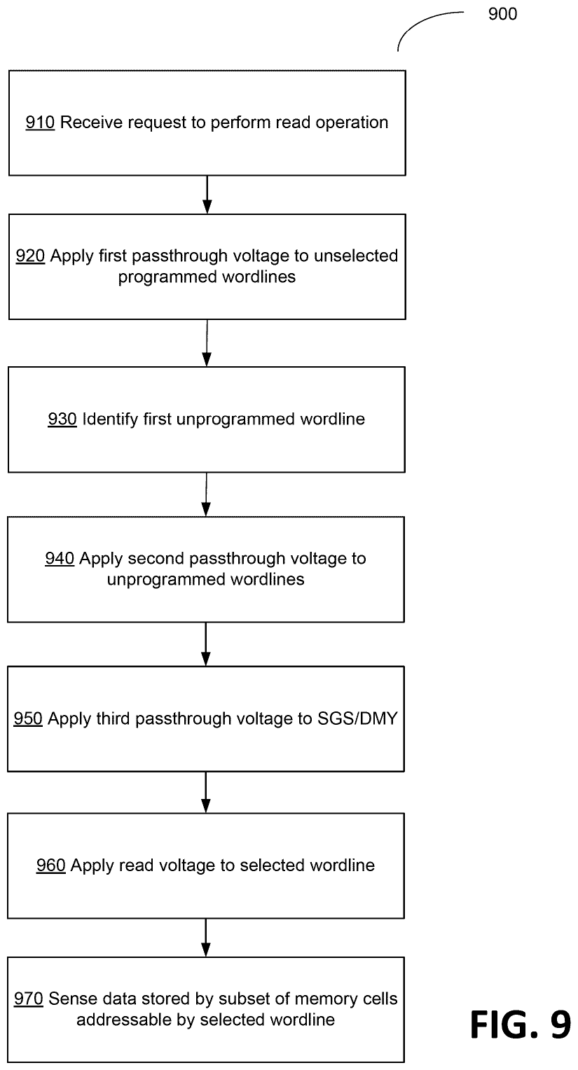

FIG. 9 schematically illustrates a flow diagram of an example method 900 of performing a memory read operation, in accordance with aspects of the present disclosure. The method 900 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 900 is performed by the memory access manager 134 of FIGS. 1A-1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 910, the processing logic implementing the method receives a request to perform a read operation with respect to a specified subset of memory cells of a memory array. In an illustrative example, the request may be received from a host system. In an illustrative example, the specified subset of the memory cells may comprise one or more memory pages.

At operation 920, the processing logic causes a first passthrough voltage to be applied to at least one unselected programmed wordline associated with the subset of memory cells.

At operation 930, the processing logic identifies the first unprogrammed wordline associated with the subset of memory cells. In an illustrative example, the processing logic may receives, from the host system, an identifier of the last programmed wordline associated with the subset of memory cells and may identify the first unprogrammed wordline by incrementing the identifier of the last programmed wordline.

At operation 940, the processing logic causes a second passthrough voltage to be applied to at least one unprogrammed wordline associated with the subset of memory cells. In an illustrative example, the second passthrough voltage may be lower, by at least a predefined value, than the first passthrough voltage. In some implementations, applying the second passthrough voltage to the unprogrammed wordlines may involve initiating, at a first moment in time, ramping up of the second passthrough voltage and then, at a second moment in time during the ramping up of the second passthrough voltage, causing the unprogrammed wordlines to be electrically disconnected from the voltage source, thus floating the unprogrammed wordlines. In some implementations, the unprogrammed wordlines may be floated responsive to determining that the ramping up voltage on the unprogrammed wordlines has reached the desired value (V_{pass_low}). In some implementations, the second moment in time follows the first moment in time by at least a first predefined period of time. In some implementations, electrically disconnecting the unprogrammed wordlines from the voltage source results in the second passthrough voltage being lower than the first passthrough voltage by at least a predefined value. In some implementations, the unprogrammed boundary wordlines (WLₙ₊₁) may be floated, by at least a second predefined period of time, later than the unprogrammed inner wordlines.

At operation 950, the processing logic causes a third passthrough voltage to be applied to at least one source side select gate (SGS) and/or at least one dummy wordline (DMY) associated with the subset of the memory cells. In some implementations, the processing logic may initiate ramping up of the third passthrough voltage at a third moment in time, which precedes the first moment in time by at least a third predefined period of time. Alternatively, the processing logic may initiate ramping down of the third passthrough voltage applied to the source side select gates (SGSs) and/or the dummy wordlines (DMY) at a fourth moment in time that is delayed, by at least a fourth predefined period of time, with respect to ramping down of the first passthrough voltage applied to the unselected programmed wordlines.

At operation 960, the processing logic causes a read voltage level to be applied to a selected wordline associated with the subset of memory cells.

At operation 970, the processing logic causes the data stored by the subset of memory cells to be sensed. In some implementations, the sensed data may be stored in a page buffer. In some implementations, the data from the sensed buffer may be transmitted to the host system.

The methods described herein apply to partially-programmed blocks, partially-good blocks (e.g., half good blocks and third good blocks), partially-programmed blocks within partially-good blocks, and/or block-by-deck implementations.

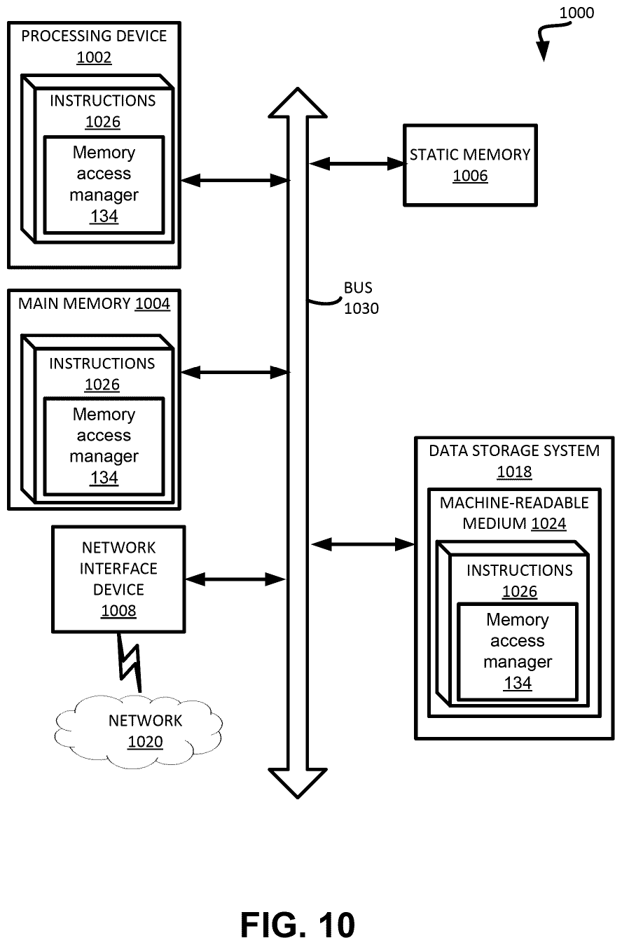

FIG. 10 illustrates an example machine of a computer system 1000 within which a set of instructions, for causing the machine to perform any one or more of the methodologies discussed herein, can be executed. In some embodiments, the computer system 1000 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to perform operations of the memory access manager 134 of FIGS. 1A-1B). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a memory cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1000 includes a processing device 1002, a main memory 1004 (e.g., read-only memory (ROM), flash memory, dynamic random access memory (DRAM) such as synchronous DRAM (SDRAM) or RDRAM, etc.), a static memory 1006 (e.g., flash memory, static random access memory (SRAM), etc.), and a data storage system 1018, which communicate with each other via a bus 1030.

Processing device 1002 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1002 can also be one or more special-purpose processing devices such as an application specific integrated circuit (ASIC), a field programmable gate array (FPGA), a digital signal processor (DSP), network processor, or the like. The processing device 1002 is configured to execute instructions 1026 for performing the operations and steps discussed herein. The computer system 1000 can further include a network interface device 1008 to communicate over the network 1020.

The data storage system 1018 can include a machine-readable storage medium 1024 (also known as a computer-readable medium) on which is stored one or more sets of instructions 1026 or software embodying any one or more of the methodologies or functions described herein. The instructions 1026 can also reside, completely or at least partially, within the main memory 1004 and/or within the processing device 1002 during execution thereof by the computer system 1000, the main memory 1004 and the processing device 1002 also constituting machine-readable storage media. The machine-readable storage medium 1024, data storage system 1018, and/or main memory 1004 can correspond to the memory sub-system 110 of FIG. 1A.

In one embodiment, the instructions 1026 include instructions to implement functionality corresponding to the memory access manager 134 of FIGS. 1A-1B. While the machine-readable storage medium 1024 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's page buffers and memories into other data similarly represented as physical quantities within the computer system memories or page buffers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array; and
a processing device, operatively coupled to the memory array, the processing device configured to:
receive a request to read a subset of memory cells of the memory array;
initiate, at a first moment in time, ramping up of a first passthrough voltage to be applied to at least one unselected programmed wordline associated with the subset of memory cells;
initiate ramping up of a second passthrough voltage to be applied to at least one unprogrammed wordline associated with the subset of memory cells;
cause, at a second moment in time during the ramping up of the second passthrough voltage applied to the at least one unselected programmed wordline, the at least one unprogrammed wordline to be electrically disconnected from a voltage source, wherein the second moment in time follows the first moment in time by at least a first predefined period of time; and
cause a read voltage level to be applied to a selected wordline associated with the subset of memory cells.

2. The memory device of claim 1, wherein electrically disconnecting the at least one unprogrammed wordline from the voltage source results in the second passthrough voltage being lower than the first passthrough voltage by at least a predefined value.

3. The memory device of claim 1, wherein the processing device is further configured to:
initiate, at a third moment in time, ramping up of a third passthrough voltage applied to at least one source side dummy wordline associated with the subset of memory cells, wherein the third moment in time precedes the first moment in time by at least a second predefined period of time.

4. The memory device of claim 1, wherein the processing device is further configured to:
cause a third passthrough voltage to be applied to at least one dummy wordline associated with the subset of memory cells;
initiate, at a third moment in time, ramping down of the first passthrough voltage applied to the at least one unselected programmed wordline; and
initiate, at a fourth moment in time, ramping down of the third passthrough voltage applied to the at least one dummy wordline, wherein the fourth moment in time follows the third moment in time by at least a second predefined period of time.

5. The memory device of claim 1, wherein the processing device is further configured to:
cause a third passthrough voltage to be applied to at least one drain side dummy wordline associated with the subset of memory cells.

6. The memory device of claim 1, wherein the processing device is further configured to:
receive an identifier of a last programmed wordline associated with the subset of memory cells; and
identify, based on the identifier of the last programmed wordline, the at least one unprogrammed wordline.

7. The memory device of claim 1, wherein the subset of memory cells comprises at least one memory page.

8. A method comprising:
receiving, by a processing device, a request to read a subset of memory cells of a memory array;
initiating, at a first moment in time, ramping up of a first passthrough voltage to be applied to at least one unselected programmed wordline associated with the subset of memory cells;
initiating ramping up of a second passthrough voltage to be applied to at least one unprogrammed wordline associated with the subset of memory cells;
causing, at a second moment in time during the ramping up of the second passthrough voltage applied to the at least one unselected programmed wordline, the at least one unprogrammed wordline to be electrically disconnected from a voltage source, wherein the second moment in time follows the first moment in time by at least a first predefined period of time; and
causing a read voltage level to be applied to a selected wordline associated with the subset of memory cells.

9. The method of claim 8, wherein electrically disconnecting the at least one unprogrammed wordline from the voltage source results in the second passthrough voltage being lower than the first passthrough voltage by at least a predefined value.

10. The method of claim 8, further comprising:
initiating, at a third moment in time, ramping up of a third passthrough voltage applied to at least one source side dummy wordline associated with the subset of memory cells, wherein the third moment in time precedes the first moment in time by at least a second predefined period of time.

11. The method of claim 8, further comprising:
causing a third passthrough voltage to be applied to at least one dummy wordline associated with the subset of memory cells;
initiating, at a third moment in time, ramping down of the first passthrough voltage applied to the at least one unselected programmed wordline; and
initiating, at a fourth moment in time, ramping down of the third passthrough voltage applied to the at least one dummy wordline, wherein the fourth moment in time follows the third moment in time by at least a second predefined period of time.

12. The method of claim 8, further comprising:
causing a third passthrough voltage to be applied to at least one drain side dummy wordline associated with the subset of memory cells.

13. The method of claim 8, further comprising:
receiving an identifier of a last programmed wordline associated with the subset of memory cells; and
identifying, based on the identifier of the last programmed wordline, the at least one unprogrammed wordline.

14. The method of claim 8, wherein the subset of memory cells comprises at least one memory page.

15. A non-transitory computer readable storage medium comprising executable instructions that, when executed by a processing device, cause the processing device to:
receive a request to read a subset of memory cells of a memory array;
initiate, at a first moment in time, ramping up of a first passthrough voltage to be applied to at least one unselected programmed wordline associated with the subset of memory cells;
initiate ramping up of a second passthrough voltage to be applied to at least one unprogrammed wordline associated with the subset of memory cells;
cause, at a second moment in time during the ramping up of the second passthrough voltage applied to the at least one unselected programmed wordline, the at least one unprogrammed wordline to be electrically disconnected from a voltage source, wherein the second moment in time follows the first moment in time by at least a first predefined period of time; and
cause a read voltage level to be applied to a selected wordline associated with the subset of memory cells.

16. The non-transitory computer readable storage medium of claim 15, wherein electrically disconnecting the at least one unprogrammed wordline from the voltage source results in the second passthrough voltage being lower than the first passthrough voltage by at least a predefined value.

17. The non-transitory computer readable storage medium of claim 15, further comprising executable instructions that, when executed by the processing device, cause the processing device to:
initiate, at a third moment in time, ramping up of a third passthrough voltage applied to at least one source side dummy wordline associated with the subset of memory cells, wherein the third moment in time precedes the first moment in time by at least a second predefined period of time.

18. The non-transitory computer readable storage medium of claim 15, further comprising executable instructions that, when executed by the processing device, cause the processing device to:
cause a third passthrough voltage to be applied to at least one dummy wordline associated with the subset of memory cells;
initiate, at a third moment in time, ramping down of the first passthrough voltage applied to the at least one unselected programmed wordline; and
initiate, at a fourth moment in time, ramping down of the third passthrough voltage applied to the at least one dummy wordline, wherein the fourth moment in time follows the third moment in time by at least a second predefined period of time.

19. The non-transitory computer readable storage medium of claim 15, further comprising executable instructions that, when executed by the processing device, cause the processing device to:
cause a third passthrough voltage to be applied to at least one drain side dummy wordline associated with the subset of memory cells.

20. The non-transitory computer readable storage medium of claim 15, further comprising executable instructions that, when executed by the processing device, cause the processing device to:
receive an identifier of a last programmed wordline associated with the subset of memory cells; and
identify, based on the identifier of the last programmed wordline, the at least one unprogrammed wordline.
